(19) United States
(12) Patent Application Publication
(10) Pub. No.: US 2025/0147530 A1
(43) Pub. Date: May 8, 2025

(54) Current-Voltage Conversion Device

(71) Applicant: Nippon Telegraph and Telephone Corporation, Tokyo (JP)

(72) Inventors: Masayuki Hashisaka, Musashino-shi, Tokyo (JP); Takafumi Akiho, Musashino-shi, Tokyo (JP); Koji Muraki, Musashino-shi, Tokyo (JP); Norio Kumada, Musashino-shi, Tokyo (JP)

(21) Appl. No.: 18/730,680

(22) PCT Filed: Jan. 31, 2022
(86) PCT No.: PCT/JP2022/003687

§ 371 Date: Jul. 19, 2024

(51) Int. Cl. G05F 1/56; G01R 19/00

(52) U.S. Cl. CPC G05F 1/561; G01R 19/0092

(57) ABSTRACT

A current-voltage conversion device that operates with low noise and a wide band is disclosed. In addition to a power supply terminal for supplying a common power supply voltage to five HEMTs (H1 to H5), a dedicated second power supply terminal for the first-stage source common circuit of the first-stage HEMT (H1) is provided. Feedback from H4 to H1 in a current-voltage conversion unit includes a feedback circuit including a plurality of resistive elements connected in series. The feedback circuit is configured by parallel connection of a feedback resistive element having a resistance value R_{FBk} and a feedback capacitor having a capacitance value C_{FBk} (k=1, 2, 3, . . . n). A small feedback capacitance C_{FB} of 1 pF or less is realized using a parasitic capacitance of a resistive element as a necessary capacitance in a feedback circuit. The time resolution of a current-voltage conversion device is enhanced.

### TECHNICAL FIELD

The present invention relates to a device for measuring a current-time waveform. More specifically, the present invention relates to a current-voltage conversion device that measures a minute current in a low temperature environment.

### BACKGROUND ART

The quantum dot technology has spread to various fields, and there is a demand for a technology for measuring a minute current output from an element in a cryogenic environment, such as state reading of a semiconductor spin quantum bit. In order to accurately measure a time waveform of a minute current in an electronic device, a highly sensitive and high-speed measurement method is required. As a device that realizes such current measurement, there is a current-voltage conversion device that converts a current into a voltage by a resistor and performs current measurement. The current-voltage conversion device amplifies the converted voltage using a low-noise amplifier, and measures the voltage with a voltmeter (for example, an oscilloscope) having sufficient time resolution. In addition, instead of using a passive circuit such as a resistor, a current can be converted into a voltage signal using a high-efficiency current-voltage conversion device including an active circuit and measured by a voltmeter having time resolution.

### CITATION LIST

### Non Patent Literature

Non Patent Literature 1: “Cryogenic amplifier for fast real-time detection of single-electron tunneling”, I. T. Vink et al., Appl. Phys. Lett. 91, 123512 2007
Non Patent Literature 2: “Single shot spin readout using a cryogenic high-electron-mobility transistor amplifier at sub-Kelvin temperatures”, L. A. Tracy et al., Appl. Phys. Lett. 108, 063101 2016
Non Patent Literature 3: “Integrated high electron mobility transistors in GaAs/AlGaAs heterostructures for amplification at sub-Kelvin temperatures”, L. A. Tracy et al., Appl. Phys. Lett. 114, 053104 2019
Non Patent Literature 4: M. Hashisaka et al., Rev. Sci. Instrum. 85, 054704 2014

### SUMMARY OF INVENTION

### Technical Problem

However, in a case where an existing current-voltage conversion device is used for measuring a time waveform of a minute current output from an element in a cryogenic environment, there are still problems such as generation of noise from the current-voltage conversion device and variation in band characteristics due to element variation.

The present invention provides a current-voltage conversion device that operates with low noise and a wide band.

### Solution to Problem

An aspect of the present invention is a current-voltage conversion device including an amplification unit that includes at least three stages each of which is formed of electronic elements, a target current being supplied to a first-stage, and amplifies a voltage generated by the target current, and a buffer unit that is connected to the amplification unit and outputs the converted voltage, in which a common first voltage is supplied to all the electronic elements, and a second voltage different from the first voltage is supplied to an input of the target current of the first-stage electronic element, and the amplification unit includes a plurality of feedback circuits connected in series that feeds back an output voltage from a final-stage of the amplification unit to the input, and each of the plurality of feedback circuits includes a resistive element.

### Advantageous Effects of Invention

The current-voltage conversion device of the present disclosure enables highly sensitive and broadband measurement of a minute current.

### BRIEF DESCRIPTION OF DRAWINGS

FIG. 1 is a diagram illustrating current-time waveform measurement by current-voltage conversion of a passive circuit.

FIG. 2 is a diagram illustrating current-time waveform measurement by current-voltage conversion of an active circuit.

FIG. 3 is a diagram illustrating a configuration of a current-voltage conversion device using a conventional HEMT.

FIG. 4 is a diagram illustrating a configuration of the current-voltage conversion device using the HEMT of the present disclosure.

FIG. 5 is a diagram illustrating frequency dependence of conversion efficiency of the current-voltage conversion device.

FIG. 6 is a diagram illustrating frequency dependence of input-referred current noise of the current-voltage conversion device.

FIG. 7 is a diagram illustrating a measurement example of a current-time waveform by the current-voltage conversion device of the present disclosure.

FIG. 8 is a diagram comparing square wave rising waveforms in the current-voltage conversion device of the present disclosure.

### DESCRIPTION OF EMBODIMENTS

A current-voltage conversion device of the present disclosure realizes highly sensitive and broadband measurement of a minute current in a cryogenic state (for example, 4 K or less). Hereinafter, the configuration and operation of the current-voltage conversion device of the present disclosure will be described while overviewing problems in the prior art and comparing with the current-voltage conversion device on which the present invention is based. Here, first, the current-voltage conversion device will be outlined.

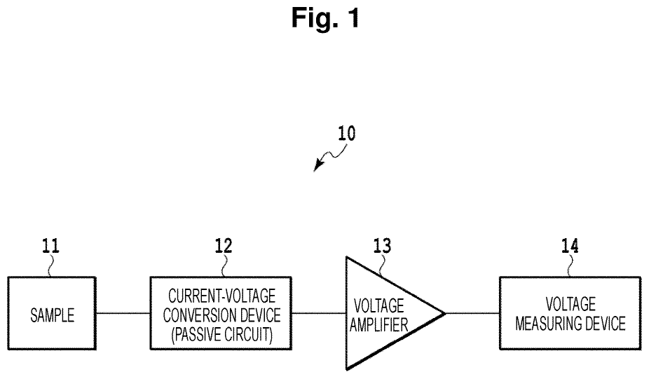

FIG. 1 is a diagram illustrating current-time waveform measurement by a current-voltage conversion device using a passive circuit. A current-time waveform measurement system 10 includes a current-voltage conversion device 12 connected to a sample 11 to be measured, a voltage amplifier 13, and a voltage measuring device 14. In the current-voltage conversion device 12 using a passive circuit such as a resistor, a current I from the sample 11 flows through the resistive element (resistance value R_{S}) which is the current-voltage conversion device 12, thereby generating the voltage V=R_{S}×I according to the Ohm's law. The resistive element (R_{S}) may be a resistance included in the sample 11, or may be a combined resistance of the resistance in the sample 11 and another resistive element.

In the current-voltage conversion device 12 using the passive circuit of FIG. 1, the efficiency of the current-voltage conversion increases as the resistance value R_{S} increases, and a small current from the sample 11 can be converted into a larger voltage. A signal-to-noise ratio in the measurement system 10 of FIG. 1 is given by the ratio between the voltage signal output from the current-voltage conversion device 12 and the input-referred noise of the voltage amplifier 13. That is, the sensitivity of the measurement system 10 is determined by the resistance value R_{S} and the input-referred noise of the voltage amplifier 13. On the other hand, the time resolution of the measurement system 10 is determined by the frequency band of the voltage amplifier 13 and the time constant of the RC filter configured by the resistive element (R_{S}) and the input capacitance C of the amplifier 13. Therefore, in the measurement system 10 using the passive element (resistance) in FIG. 1, the higher the resistance value R_{S}, the higher the sensitivity of the measurement, while the speed (measurement band) conversely decreases. Regarding the resistance value R_{S}, there is a trade-off relationship between the measurement sensitivity and the measurement speed.

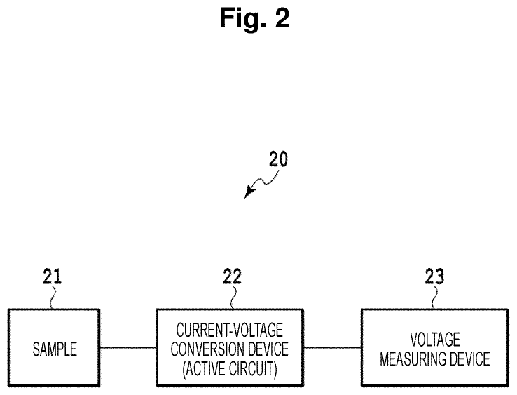

FIG. 2 is a diagram illustrating current-time waveform measurement by the current-voltage conversion device using an active circuit. A current-time waveform measurement system 20 includes a current-voltage conversion device 22 connected to a sample 21 to be measured and a voltage measuring device 23. In the measurement system 20, one current-voltage conversion device 22 including an active circuit plays two roles of current-voltage conversion and signal amplification. The sensitivity of the current measurement in the measurement system 20 is determined by the input-referred current noise of the current-voltage conversion device 22, and the time resolution is determined by the frequency band region of the current-voltage conversion device 22.

In state reading of semiconductor spin quantum bits and the like, a time waveform of a minute current output from an element in a cryogenic environment with an absolute temperature of 1 K or less may be measured. When minute current measurement is performed in such a cryogenic environment, the measurement system 10 using the passive circuit of FIG. 1 is widely used. In a typical configuration, current-voltage conversion is performed using the current-voltage conversion device 12 in a cryogenic environment. Further, the voltage signal is taken out to room temperature by the coaxial cable, and the voltage signal is amplified and measured by the voltage amplifier 13 in a room temperature environment. In the minute current measurement by the measurement system 10 in FIG. 1, input-referred noise derived from thermal noise of the voltage amplifier 13 in a room temperature environment is large, and thus sensitivity may be insufficient. In addition, the parasitic capacitance of the coaxial cable connecting the cryogenic environment and the room temperature environment increases an input capacitance C of the voltage amplifier 13. Since the coaxial cable typically has a parasitic capacitance of about 100 pF per meter, the RC time constant of the voltage amplifier 13 increases, and the time resolution may be insufficient. The decrease in the time resolution of the current measurement is particularly noticeable in a case where the resistance value R_{S} of the current-voltage conversion device 12 is large.

In order to solve the problem of the sensitivity and speed of the current measurement in the measurement system 10 of FIG. 1 described above, the noise derived from the thermal noise of the voltage amplifier 13 can be reduced by operating the voltage amplifier 13 at a low temperature in the vicinity of the sample 11 in a cryogenic environment. With this configuration, the distance between the sample 11 and the voltage amplifier 13 can be shortened, the parasitic capacitance of the cable can be suppressed, and the time resolution can be improved.

Non Patent Literatures 1 to 3 relate to time waveform measurement of a current using a source common circuit as a low-temperature voltage amplifier. In Non Patent Literature 1, in order to measure a current generated in a sample in a dilution refrigerator (temperature: 40 mK), a commercially available field effect transistor (FET) having low power consumption is installed on a plate at a temperature of about 1 K in the refrigerator. By the operation in the cryogenic environment, thermal noise generated in the source common circuit of the FET is suppressed, and the parasitic capacitance of the cable is reduced. Also in Non Patent Literature 2, a commercially available FET is installed in a cryogenic environment very close to a sample, and further thermal noise suppression and parasitic capacitance reduction are successful. In Non Patent Literature 3, a self-made FET is operated on one semiconductor substrate together with a sample to realize an amplifier with lower noise than a commercially available FET, and the sample and the amplifier are connected to each other at the shortest distance to minimize the parasitic capacitance, thereby speeding up the current measurement.

As can be seen from the above example, in order to suppress the influence of the parasitic capacitance C due to the cable between the sample and the current-voltage conversion device, it is desirable to place the voltage amplifier and the sample in the same temperature environment. However, this configuration causes another problem that the sample to be cooled is warmed up by heat generated from the voltage amplifier. In addition, as in Non Patent Literature 3, the configuration in which the sample and the FET are fabricated on the same semiconductor substrate to minimize the parasitic capacitance C is limited to the application in which the voltage amplifier and the sample are integrally used, and lacks versatility of the measurement system. Furthermore, since there is a limit to the suppression of the parasitic capacitance on the input side of the voltage amplifier, it is difficult to increase the speed in a case where the resistance value R of the sample is large, and the time resolution in Cited Literatures 1 to 3 is only about 1 μs.

As described in Non Patent Literature 4, the inventors have developed a cryogenic current-voltage conversion device using a high electron mobility transistor (HEMT). The present invention to be described later improves the current-voltage conversion device disclosed in Cited Literature 4 to be suitable for current-time waveform measurement by the current-voltage conversion device using the active circuit illustrated in FIG. 2. Hereinafter, a configuration and a problem of the current-voltage conversion device will be described.

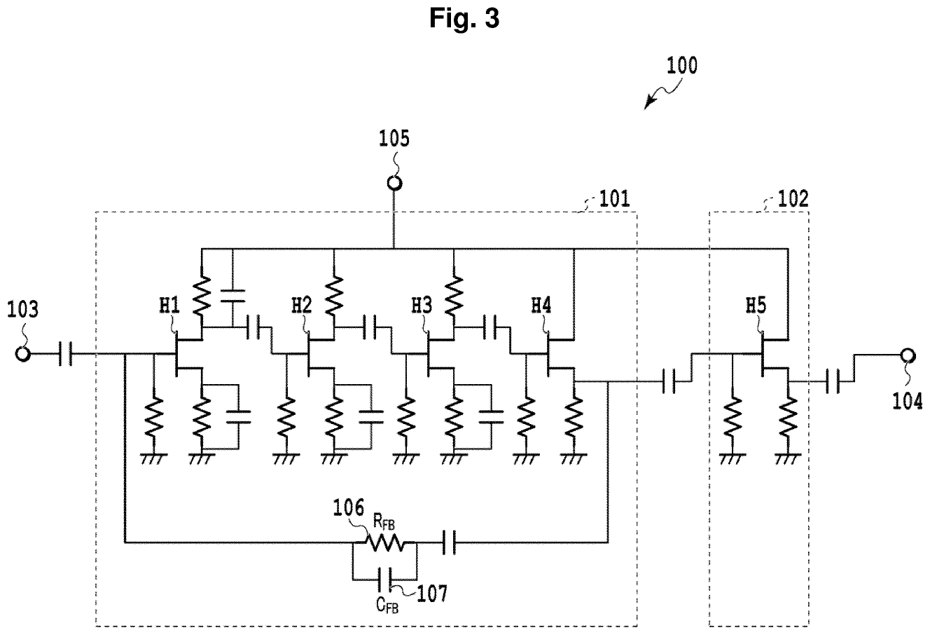

FIG. 3 is a diagram illustrating a circuit configuration of a current-voltage conversion device using the HEMT. A current-voltage conversion device 100 includes a current-voltage conversion unit 101 including four HEMTs (H1 to H4) in a preceding stage and an output stage source follower unit 102 including one HEMT (H5) in a subsequent stage. The current-voltage conversion unit 101 includes a source common circuit (source ground circuit) including three HEMTs (H1 to H3) on the preceding stage side and a source follower circuit including a HEMT (H4) of the fourth stage. In the current-voltage conversion device 100, power is simultaneously supplied from one power supply terminal 105 to the five HEMTs. In the source common circuits (H1 to H3), a resistor and a capacitor are connected in parallel to the source of the HEMT, and an effective bias is applied to the gate of the HEMT by a self-bias method. The input-referred current noise of the current-voltage conversion device 100 is mainly determined by the input voltage noise and the input current noise of the source common circuit by the first-stage HEMT (H1) and the thermal noise generated in a feedback resistor 106 (R_{FB}). In addition, the time resolution of the current-voltage conversion device 100 is mainly determined by an RC time constant based on the resistance value R_{FB} of the feedback resistor 106 and the capacitance value C_{FB} of a feedback capacitor 107. According to the configuration of FIG. 3, since only one power supply wiring is required, heat flowing into a cooling device from the outside via the electric wiring can be suppressed, and a load of the cooling device can be reduced, which is suitable for current measurement for cryogenic temperature.

The current-voltage conversion device 100 in FIG. 3 has a simple configuration for supplying a single voltage from one power supply terminal 105, but cannot set a bias focusing on noise characteristics for the first-stage HEMT (H1). The bias setting for minimizing the noise characteristics with respect to the first-stage HEMT (H1) cannot be performed in response to the variation in the element characteristic of the HEMT when the HEMT is used at a cryogenic temperature. In addition, the feedback resistor 106 and the feedback capacitor 107 that determine noise characteristics and time resolution require a capacitance value smaller than 1 pF for stable current measurement in a cryogenic environment. The capacitance value smaller than 1 pF is equal to or less than the parasitic capacitance component of the resistive element 106 and the capacitor 107, and the parasitic capacitance has a large influence on the characteristics of the source common circuit of the current-voltage conversion unit 101. Since a stable feedback capacitance value cannot be realized, noise characteristics and time resolution in current measurement of the current-voltage conversion device 100 vary. In addition, the band of the current-voltage conversion unit is limited due to the parasitic capacitance of the capacitor described above, and the time resolution is also limited. The current-voltage conversion device of the present disclosure solves the above-described problem of the current-voltage conversion device 100 of FIG. 3.

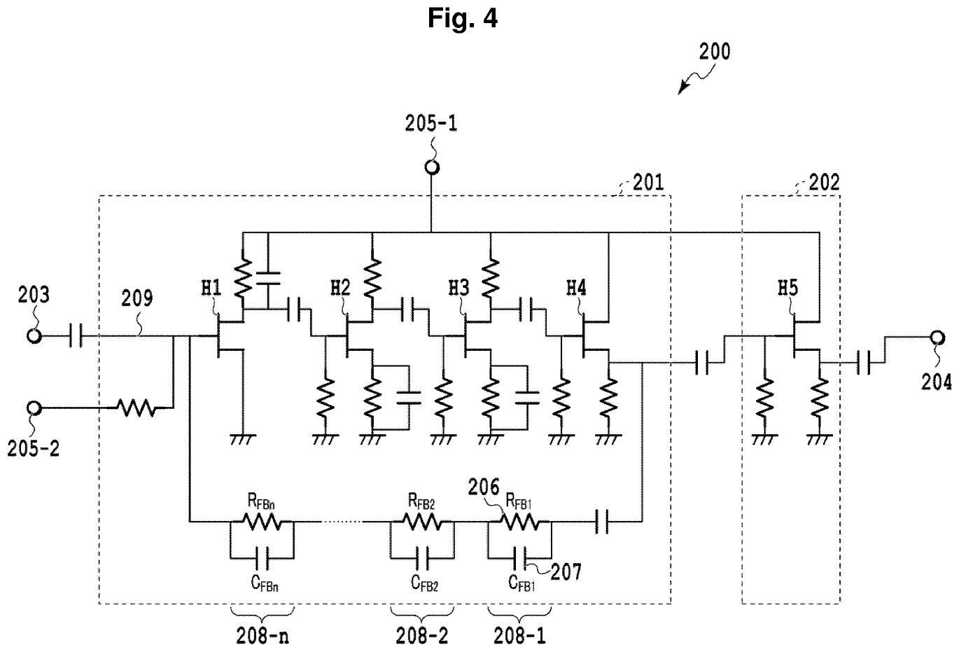

FIG. 4 is a diagram illustrating a circuit configuration of a current-voltage conversion device using the HEMT of the present disclosure. A current-voltage conversion device 200 includes a current-voltage conversion unit 201 including four HEMTs (H1 to H4) and an output stage source follower unit 202 including one HEMT (H5) in a subsequent stage. The minute current to be measured is input to a current input terminal 203. The time waveform of the minute current is obtained as a voltage waveform of a voltage output terminal 204. In the current-voltage conversion device 200, power is simultaneously supplied from one power supply terminal 205 to the drains of the five HEMTs, which is the same as the configuration of the related art in FIG. 3. There are the following two differences from the configuration of the current-voltage conversion device 100 of the related art in FIG. 3.

A first difference is that, in addition to a power supply terminal 205-1 for supplying the power supply voltage to the five HEMTs (H1 to H5), a second power supply terminal 205-2 dedicated to the first-stage source common circuit of the first-stage HEMT (H1) is provided. As described later, since it takes a large cost to align element characteristics of a plurality of low-temperature HEMTs, characteristics of H1 to H5 generally vary in an actual current-voltage conversion device. Since the noise characteristic of the first-stage source common circuit according to H1 greatly affects the noise characteristic of the entire device, it is important to set the operating point of H1 among the five HEMTs as the optimum point of the noise characteristic. In the current-voltage conversion device 200, by independently supplying the gate voltage from a second power supply terminal 205-2 to H1, the operating point of the source common circuit of the initial stage can be optimized even if there is a variation in characteristics with the plurality of other HEMTs. As a result, the input-referred noise of the entire current-voltage conversion device 200 can be significantly suppressed.

A second difference is that feedback from H4 to H1 in the current-voltage conversion unit 201 is performed by the plurality of divided feedback circuits 208-1 to n. One feedback circuit is configured by parallel connection of a feedback resistor 206 having a resistance value R_{FBk} and a feedback capacitor 207 having a capacitance value C_{FBk} (k=1, 2, 3, . . . n). That is, the plurality of feedback circuits 208-1 to n are connected in series. However, as will be described later, in a case where a high-speed time response is required, the capacitance value C_{FBk} of the feedback capacitor is realized by the parasitic capacitance of the resistive element, so that the feedback capacitor is unnecessary. That is, the feedback circuit includes only a plurality of resistive elements connected in series.

The current-voltage conversion device 200 of the present disclosure converts the input current I to the current input terminal 203 into the voltage V of the voltage output terminal 204 as in the following equation.

$$V = {Z}_{F B} \times I \qquad Equation ( 1 )$$

Here, ZEB is the impedance of the feedback circuit from H4 to H1. The current-voltage conversion device 200 is normally operated in a frequency range lower than an upper limit frequency fc of the following equation so that the influence of the capacitance value C_{FB} of the feedback capacitor is sufficiently reduced.

$$fc = \frac{1}{2 π {R}_{FB} {C}_{FB}} \qquad Equation ( 2 )$$

In a band lower than the upper limit frequency fc of the above equation, the impedance of the feedback circuit can be generally regarded as a resistance value of the feedback resistor as in the following equation.

$${Z}_{FB} = {R}_{FB} \qquad Equation ( 3 )$$

In general, a feedback capacitor (for example, the capacitor 107 in FIG. 3) in a feedback circuit compensates for a phase shift caused by a capacitive component of an impedance connected to a current input terminal of a current-voltage conversion device with a capacitive component of the feedback capacitor to stabilize operation of the device. On the other hand, when the upper limit frequency fc is defined as in Equation (2) and the capacitance value C_{FB} of the feedback capacitor increases, the operating frequency band of the current-voltage conversion device is narrowed. The current-voltage conversion device 200 of the present disclosure can provide high-speed current-time waveform measurement by suppressing the feedback capacitance value C_{FB} as small as possible within a range in which the device operates stably.

In applications such as semiconductor spin quantum bit state reading, the internal resistance of a sample is typically about 10 kΩ to 100 kΩ. When the current-voltage conversion device 200 of FIG. 4 is used in a temperature environment of 1 K to 4 K in the dilution refrigerator, the input capacity at the current input terminal 203 is about 10 pF to 50 pF. The input capacitance value mainly includes a parasitic capacitance of a coaxial cable connecting the sample and the current-voltage conversion device 200. In the case of the sample resistance value and the input capacitance value, the feedback capacitance value C_{FB} necessary for stabilizing the circuit by phase compensation in the current-voltage conversion unit 201 is 1 pF or less. That is, in order to widen the frequency band of the current-voltage conversion device 200 and perform high-speed current-time waveform measurement, means for adjusting the feedback capacitance value C_{FB} to a small value in a low temperature environment is required.

However, it is difficult to stably control the feedback capacitance value C_{FB} in a region of 1 pF or less in an actual resistive element or capacitor. This is because the resistive element has a parasitic capacitor parallel to the resistive element as an equivalent circuit, and has a parasitic capacitance of about 0.5 pF determined by the shape of the resistive element, and it is difficult to control the parasitic capacitance. As long as the feedback circuit is constituted by a single resistive element 106 as in the configuration of the conventional technique in FIG. 3, it is not possible to realize the feedback capacitor 107 having the capacitance value C_{FB} smaller than the parasitic capacitance value of the resistor.

In the current-voltage conversion device 200 of the present disclosure of FIG. 4, feedback from H4 to H1 of the current-voltage conversion unit 201 is realized by series connection of a plurality of feedback circuits 208-1 to 208-n. In each feedback circuit, the capacitance value C_{FB} of the entire feedback circuit can be easily set to 1 pF or less by combining the values of a resistive element 206 and the capacitor 207 including the parasitic capacitance value. For example, a resistive element having a resistance value of R_{FB}/3 and its parasitic capacitance C_{P} can configure one feedback circuit. That is, the feedback circuit is configured only with the resistive element without using a capacitor as an individual component in the feedback circuit. In a case where the feedback circuits 208-1 to 208-n in FIG. 4 realize an equivalent feedback resistance value R_{FB} by connecting three resistive elements in series (3-stage configuration), the upper limit frequency fc shown in Equation (2) is approximately the following equation.

$$fc ≅ \frac{1}{\frac{2}{3} π {R}_{FB} {C}_{p}} \qquad Equation ( 4 )$$

Comparing Equations (2) and (4), by connecting the three feedback circuits in series, the same effect as that of suppressing the capacitance value C_{P} of the entire feedback circuit to substantially ⅓ can be obtained. In the entire feedback circuit, since three resistors having a resistance value of R_{FB}/3 are connected in series, a required resistance value R_{FB} of the feedback resistor can be generally obtained. The parasitic capacitance value of the resistor can be managed within a certain error range if the size and structure of the component to be used are determined. Therefore, C_{FB} of 1 pF or less can be realized by selecting the known parasitic capacitance value, the resistance value of the resistive element, and the number of feedback circuits (the number of stages) connected in series. It should be noted that when the number of stages of the feedback circuit is different, Equation (4) in the case of the 3-stage configuration is different. As described above, the feedback circuit having the characteristics required in the current-voltage conversion unit 201 is divided into a plurality of feedback circuits, the parasitic capacitance of the resistive element is used as the required capacitance in each feedback circuit, and a small feedback capacitance C_{FB} can be realized as series connection of these feedback circuits. As a result, the capacitance value C_{FB} of 1 pF or less can be realized, and the time resolution of the current-voltage conversion device can be enhanced.

The above-described two differences between the respective current-voltage conversion devices of FIGS. 3 and 4 have great significance in the measurement of a minute current at a cryogenic temperature. Each of the current-voltage conversion devices of FIGS. 3 and 4 uses a plurality of HEMTs. On the premise of use at room temperature, an HEMT having uniform characteristics can be easily selected, whereas such selection is difficult on the premise of operation at a low temperature. This is because, in a low temperature environment, the influence of impurities in the semiconductor is larger than that at room temperature, and thus the characteristic variation of the HEMT is large, and the characteristic variation cannot be determined from the appearance. In order to select a low-temperature HEMT, it is necessary to test a large number of HEMTs in a low-temperature environment, which causes financial and temporal costs. In addition, characteristics of the HEMT at a low temperature may be different depending on cooling conditions such as a cooling rate, and it is technically difficult to accurately compare test results for each step of cooling different HEMTs.

By including the second power supply terminal 205-2 dedicated to the first-stage source common circuit, which is the first difference, excellent noise performance can be stably extracted even if the characteristics of the five HEMTs are different for each HEMT or the characteristics of the first-stage HEMT vary for each device. By independently adjusting the bias to the gate of the first-stage HEMT (H1) and setting the operating point of the first-stage HEMT (H1) as the optimum point of the noise characteristic, the input-referred noise of the entire current-voltage conversion device 200 can be suppressed.

With the configuration in which the plurality of feedback circuits are connected in series, which is the second difference, the feedback capacitance of 1 pF or less is realized using the parasitic capacitance of the resistive element, and high-speed current-time waveform measurement is realized. In the feedback circuit using a single resistor and capacitor illustrated in FIG. 3, a feedback capacitance value of 1 pF or less cannot be realized. The feedback circuit includes a resistive element and a capacitor by a parasitic capacitance thereof, and a plurality of feedback circuits are connected in series, so that parameter adjustment means for obtaining a desired feedback characteristic can be obtained. The parasitic capacitance value can be ascertained within a certain error range according to the specific size and shape of the resistive element.

Accordingly, the current-voltage conversion device 200 of the present disclosure is implemented as including an amplification unit 201 that includes at least three stages each of which is formed of electronic elements (H1 to H5), a target current being supplied to a first-stage, and amplifies a voltage generated by the target current, and a buffer unit 202 that is connected to the amplification unit and outputs the converted voltage, in which a common first voltage is supplied to all the electronic elements, and a second voltage different from the first voltage is supplied to an input 209 of the target current of the first-stage electronic element, and the amplification unit includes a plurality of feedback circuits 208-1 to 208-n connected in series that feeds back an output voltage from a final-stage H4 of the amplification unit to the input H1, and each of the plurality of feedback circuits includes a resistive element 206.

As described above, since the current-voltage conversion device 200 of the present disclosure is configured by a combination of a plurality of low-temperature HEMTs, the performance varies for each individual device. Therefore, it is also necessary to perform trial and error of the parameters of the feedback resistance value R_{FB} and the feedback capacitance value C_{FB} of the feedback circuit for each device. In this trial and error, it is necessary to cool the present device to a low temperature and perform a test, which is a complicated and troublesome process, and costs are generated. In contrast to a single resistive element of a single feedback circuit in the prior art, by dividing the feedback circuit into a plurality of resistive elements, a combination of resistance values and the number of resistive elements connected in series can be flexibly changed. Since simple parameter adjustment means can be obtained, it is also useful to reduce the test cost, and it is possible to flexibly adjust the noise characteristic and the time resolution characteristic.

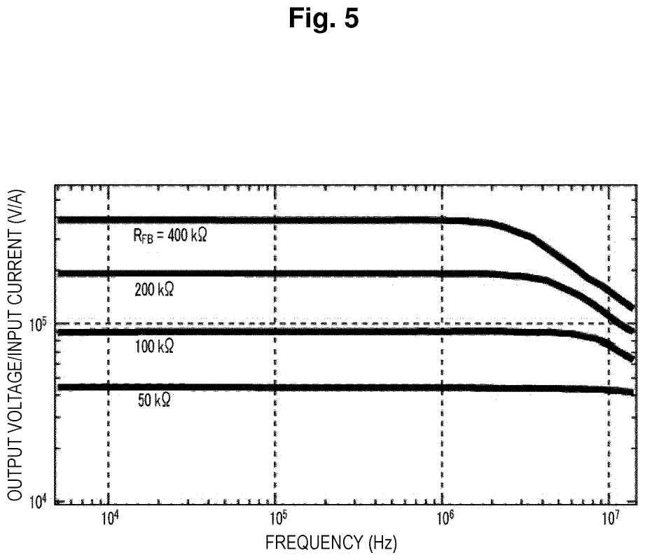

FIG. 5 is a diagram illustrating frequency dependence of conversion efficiency of the current-voltage conversion device of the present disclosure. In the example illustrated in FIG. 5, the feedback circuit of the current-voltage conversion unit 201 in FIG. 4 includes four feedback circuits, and four resistive elements are connected in series. The feedback capacitor of each feedback circuit in FIG. 4 is realized by the parasitic capacitance of each resistive element. Therefore, the feedback circuit from the drain of H4 to the gate of H1 in FIG. 4 includes DC cut-off C and four resistive elements. FIG. 5 illustrates the frequency characteristics of the output voltage/input current (V/I) with the total resistance value R_{FB} of the four feedback circuits as a parameter (50, 100, 200, 400 kΩ). For each total resistance value R_{FB}, four resistance values were selected to widen the frequency band as much as possible, and as an example, two resistive elements having a resistance value half the value of each REB and two resistive elements of 1 kΩ were used. Specifically, in a case of R_{FB}=400 kΩ, two resistive elements of 200 kΩ and two resistive elements of 1 kΩ were selected. Since the resistance value of the resistive element has an error of several percent, the total resistance value of the four resistance values was regarded as R_{FB}=400 kΩ.

Referring to FIG. 5, as the value of the total resistance value R_{FB} of the feedback circuit decreases, the current-voltage conversion efficiency decreases, while the frequency band increases. In a case where the total resistance value REB is 50 kΩ, a constant current-voltage conversion efficiency is realized up to about 10 MHZ. In the single feedback circuit (resistive element 100 kΩ, capacitance value of capacitor 0.3 pF) of the prior art illustrated in FIG. 3, the frequency at which a constant current-voltage conversion efficiency (9×10⁴) can be obtained was 1 MHZ). The configuration of the present disclosure including the plurality of feedback circuits connected in series indicates that the operation can be performed in a broadband of about 10 times that of the conventional technique.

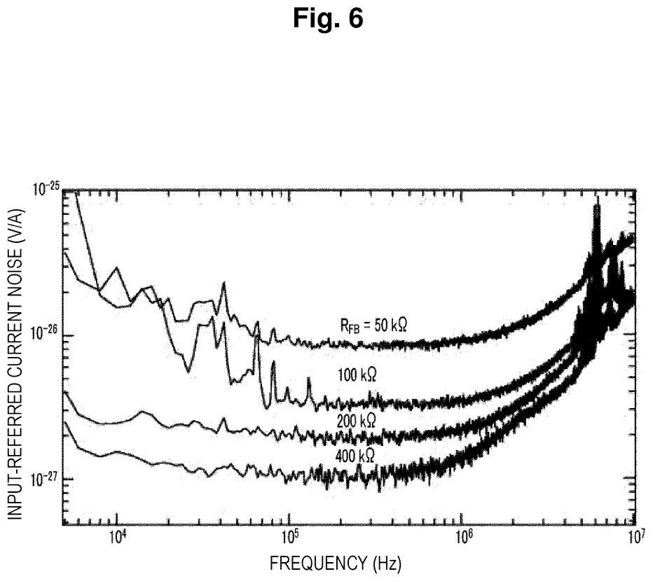

FIG. 6 is a diagram illustrating frequency dependence of input-referred current noise of the current-voltage conversion device of the present disclosure. The frequency characteristic of the input-referred current noise is illustrated using the same total resistance value R_{FB} as in the example illustrated in FIG. 5 as a parameter (50, 100, 200, 400 kΩ). When the value of the REB increases, the input-referred current noise decreases. In a case where the R_{FB} is 400 kΩ, the input-referred current noise is 1×10⁻²⁷A2/Hz in the band of 10 kHz to 1 MHz. In the single feedback circuit (resistive element 100 kΩ, capacitance value of capacitor 0.3 pF) of the related art illustrated in FIG. 3, the frequency was 5×10⁻²⁷A²/Hz in the band of 70 kHz to 600 kHz with the smallest input-referred noise. The configuration with a dedicated second power supply terminal to H1 and a plurality of feedback circuits shows that the current-voltage conversion device can be operated at a current noise level of ⅕ compared to the prior art.

As described above, in the current-voltage conversion device of the present disclosure, when the total resistance value R_{FB} of the feedback circuit increases, the input-referred current noise is suppressed, but the frequency band conversely narrows. Therefore, the value of the REB can be appropriately set according to the application of the current-voltage conversion device, a noise characteristic and a band characteristic can be balanced, and desired performance can be satisfied. As a typical example, focusing on the case where the REB is 100 kΩ in FIGS. 5 and 6, the frequency band is widened by about 5 times and the input-referred current noise is reduced to about ⅗ (minus 40%) as compared with the case of the conventional technique.

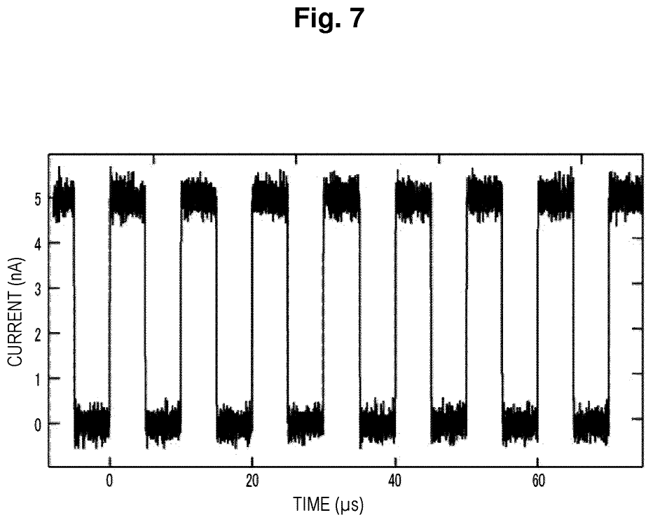

FIG. 7 is a diagram illustrating a measurement example of a current-time waveform using the current-voltage conversion device of the present disclosure. This is an example in which a time waveform of a square wave current having an amplitude of 5 nAp-p and 100 kHz is observed using the current-voltage conversion device (R_{FB}=200 kΩ) having the configuration of FIG. 4. From the time waveform of FIG. 7, it can be seen that the falling and the rising of the square wave current can be accurately measured.

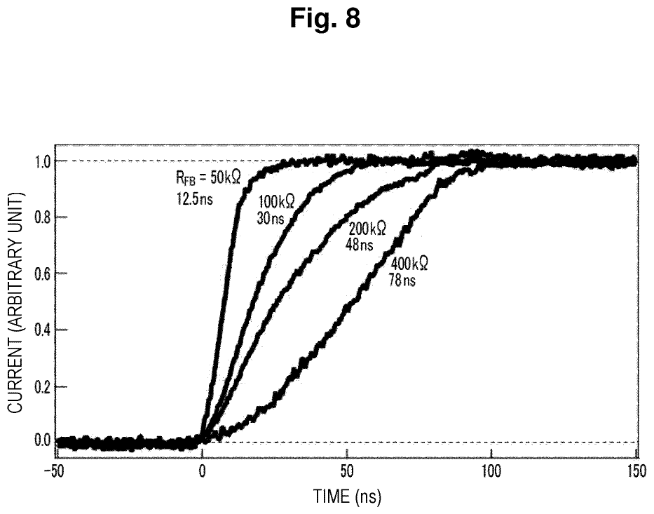

FIG. 8 is a diagram comparing square wave rising waveforms in the current-voltage conversion device of the present disclosure. The time axis of the rising portion of the current square wave illustrated in FIG. 7 is enlarged with the same total resistance value REB as in the example illustrated in FIG. 5 as a parameter (50, 100, 200, 400 kΩ). It can be seen that the smaller the value of the total resistance value R_{FB} of the feedback circuit, the wider the frequency band of the current-voltage conversion device, and the current change can be evaluated with high time resolution. For example, in a case where the R_{FB} is 50 kΩ, the time resolution is 12.5 ns from the rising characteristic of FIG. 8. Compared with the time resolution of 1 us in the disclosure of Cited Literatures 1 to 3, the measurement of the rising portion of the current waveform is considerably speeded up.

The current-time waveform measurement using the current-voltage conversion device of the present disclosure is useful for state reading of semiconductor spin quantum bits. In the state reading of the semiconductor spin quantum bits, it is known to use an auxiliary quantum dot and a charge meter capacitively coupled with the auxiliary quantum dot in order to read the electron spin in the quantum bit. When the charge amount of the auxiliary quantum dot changes according to the direction of the electron spin in the quantum bit, the electric resistance of the charge meter changes through capacitive coupling, and the current flowing through the charge meter changes. The closed circuit of the charge meter is cut off and connected to the input terminal 203 of the current-voltage conversion device of FIG. 4, and the current-time waveform is measured, whereby the state of the semiconductor spin quantum bit can be evaluated. In FIG. 2, by placing a sample containing a semiconductor spin quantum bit and the current-voltage conversion device 200 of the present disclosure illustrated in FIG. 4 in a cryogenic environment (for example, 4 K or less), the current of the charge meter can be measured with high sensitivity and high speed.

The current-voltage conversion device of the present disclosure is suitable for state reading of a semiconductor spin quantum bit and the like, but its application is not limited as long as it measures a minute current at a cryogenic temperature. This is effective for current measurement requiring high speed and high sensitivity.

### INDUSTRIAL APPLICABILITY

The current-voltage conversion device of the present invention can be used for measuring a minute current.

1. A current-voltage conversion device comprising:
an amplification unit that includes at least three stages each of which is formed of electronic elements, a target current being supplied to a first-stage, and amplifies a voltage generated by the target current; and
a buffer unit that is connected to the amplification unit and outputs the converted voltage, wherein
a common first voltage is supplied to all the electronic elements, and a second voltage different from the first voltage is supplied to an input of the target current of the first-stage electronic element, and
the amplification unit includes a plurality of feedback circuits connected in series that feeds back an output voltage from a final-stage of the amplification unit to the input, and each of the plurality of feedback circuits includes a resistive element.

2. The current-voltage conversion device according to claim 1, wherein the current-voltage conversion device operates in a cryogenic environment of 4 K or less.

3. The current-voltage conversion device according to claim 1, wherein
the electronic element is a field effect transistor,
the amplification unit is a four-stage common source voltage amplification stage, and a final-stage constitutes a source follower, and
the buffer unit is a source follower constituted by the electronic element.

4. The current-voltage conversion device according to claim 3, wherein the field effect transistor is a high-electron-mobility transistor (HEMT).

5. The current-voltage conversion device according to claim 1, wherein each of the plurality of feedback circuits further includes a capacitor in parallel with the resistive element.

6. The current-voltage conversion device according to claim 1, wherein the target current reflects a state of a quantum bit.

7. The current-voltage conversion device according to claim 2, wherein
the electronic element is a field effect transistor,
the amplification unit is a four-stage common source voltage amplification stage, and a final-stage constitutes a source follower, and
the buffer unit is a source follower constituted by the electronic element.

8. The current-voltage conversion device according to claim 2, wherein each of the plurality of feedback circuits further includes a capacitor in parallel with the resistive element.

9. The current-voltage conversion device according to claim 3, wherein each of the plurality of feedback circuits further includes a capacitor in parallel with the resistive element.

10. The current-voltage conversion device according to claim 4, wherein each of the plurality of feedback circuits further includes a capacitor in parallel with the resistive element.

11. The current-voltage conversion device according to claim 2, wherein the target current reflects a state of a quantum bit.

12. The current-voltage conversion device according to claim 3, wherein the target current reflects a state of a quantum bit.

13. The current-voltage conversion device according to claim 4, wherein the target current reflects a state of a quantum bit.

14. The current-voltage conversion device according to claim 5, wherein the target current reflects a state of a quantum bit.
